(19) United States
(12) Patent Application Publication
(10) Pub. No.: US 2016/0133711 A1
(43) Pub. Date: May 12, 2016

(54) METHOD OF FABRICATING SOURCE/DRAIN REGION AND SEMICONDUCTOR STRUCTURE HAVING SOURCE/DRAIN REGION FABRICATED BY THE SAME

(71) Applicant: INOTERA MEMORIES, INC., Taoyuan County (TW)

(72) Inventors: YU NA CHOU, NEW TAIPEI CITY (TW); CHEN-KANG WEI, TAOYUAN COUNTY (TW); YI WEI CHUANG, TAIPEI CITY (TW); RONG ZHEN CHEN, NEW TAIPEI CITY (TW); CHUN WEI YO, KEELUNG CITY (TW)

(21) Appl. No.: 14/534,882

(22) Filed: Nov. 6, 2014

(51) Int. Cl. H01L 29/36; H01L 29/43; H01L 29/417; H01L 21/265; H01L 21/324

(52) U.S. Cl. CPC H01L 29/36; H01L 21/26513; H01L 21/324; H01L 29/41725; H01L 29/43

(57) ABSTRACT

A method of fabricating source/drain region in a substrate includes the steps of: introducing an ion beam-line of a first material to a surface of the substrate at a first energy and a first dosage to implant the substrate with dopants of a first conductive type; and subsequently, introducing a plasma of a second material to the surface. The ion beam-line is introduced, at a second energy and a second dosage to implant the substrate with dopants of the first conductive type. The second dosage is greater than the first dosage and the implant depth of the plasma is less than the implant depth of the ion beam-line.

### BACKGROUND

1. Field of the Invention

The instant disclosure relates to method of fabricating semiconductor structure and fabricating semiconductor structure fabricated by the same, and pertains particularly to method of fabricating source/drain region in substrate and semiconductor structure having source/drain region fabricated by the same.

2. Description of Related Art

Forming of an impurity diffusion layer ordinarily comprises an ion implantation process of implanting ionized impurities into a substrate. A depth of the pn junction formed by the beam-line ion implantation is limited. For example, the shallow introduction of boron impurity is difficult in the beam-line ion implantation. That is, it is difficult to set acceleration energy of boron ions to low energy, and hence, the depth of the ion introduced region is limited. Recently, a doping process known as plasma doping, or “PLAD” has been attracting attention as a technique which can efficiently form the shallower junction. However, in the plasma doping, the dopant purity of the ion introduced region is limited.

Also, there has been a demand for a control technique with high accuracy to introduce impurity onto a surface of a substrate. In cases where a thermal treatment process is performed after the ion implantation process and even where a rapid thermal process (RTP) is used, a part of the substrate, which is at a depth deeper than that of the part of the substrate into which the ions are implanted, may be heated. Namely, by heating, silicon crystals at a location deeper than the implantation layer are excited, and the impurities diffuse into the excited crystals. By the impurities diffusing in this way, diffusion depth increases to a significant degree, and it is hard to control the substantial junction depth, in which occurrence of short channel effect is not prevented, resulting to the deterioration in the reliability of the device.

### SUMMARY OF THE INVENTION

The embodiment of the instant disclosure provides a method of fabricating source/drain region in substrate and a semiconductor structure having source/drain region fabricated by the same. The method of fabricating source/drain region in substrate utilizes a step of ion beam-line implantation with relative low energy compared to the conventional beam-line implantation, to form an initial ion introduced portion of better dopant purity in the substrate, and utilizes a subsequent step of plasma doping carried out onto the surface where the ion beam-line is introduced, to form a second ion introduced portion of preferred dopant concentration. Meanwhile, the dopants boron in the initial ion introduced region are driven into a deeper region within the substrate without any thermal treatment, so as to facilitate the formation of a first ion introduced portion of preferred dopant purity surrounding the shallow second ion introduced portion.

The method of fabricating source/drain region in a substrate in accordance with the instant disclosure comprises the following steps. First, an ion beam-line of a first material is introduced to a surface of the substrate at a first energy and a first dosage to implant the substrate with dopants of a first conductive type. And then, a plasma of a second material is introduced to the surface. The ion beam-line is introduced, at a second energy and a second dosage to implant the substrate with dopants of the first conductive type, in which the second dosage is greater than the first dosage and the implant depth of the plasma is less than the implant depth of the ion beam-line.

Another aspect of the instant disclosure provides a semiconductor structure having source/drain region. The semiconductor structure in accordance with the instant disclosure comprises a substrate, a gate disposed on a surface of the substrate, and a source/drain region for the gate disposed within the substrate. The source/drain region has a first ion introduced portion and a second ion introduced portion extending from the surface of the substrate into the substrate. The first ion introduced portion surrounds the second ion introduced portion and does not underlap the gate. The second ion introduced portion has a dopant concentration greater than that of the first ion introduced portion. The first ion introduced portion has a dopant purity greater than that of the second ion introduced portion.

These and other features and advantages of the present invention will be described in, or will become apparent to those of ordinary skill in the art in view of, the following detailed description of the exemplary embodiments of the present invention.

### BRIEF DESCRIPTION OF THE DRAWINGS

The novel features believed characteristic of the invention are set forth in the appended claims, the invention itself, however, as well as a preferred mode of use, further objectives and advantages thereof, will best be understood by reference to the following detailed description of an illustrative embodiments when read in conjunction with the accompanying drawings, wherein:

FIG. 1A illustrates a partial cross-sectional view of a semiconductor structure during one exemplary fabrication step in accordance with an embodiment of the instant disclosure;

FIG. 1B illustrates a partial cross-sectional view of the semiconductor structure in accordance with the embodiment of the instant disclosure; and

FIG. 2 is a diagram showing SIMS data showing impurity profiles of a source/drain region of the semiconductor structure obtained in an embodiment of the instant disclosure.

### DETAILED DESCRIPTION OF THE PREFERRED EMBODIMENTS

The instant disclosure will be described more specifically with reference to the following embodiments. It is to be noted that the following descriptions of preferred embodiments are provided herein for purpose of illustration and description. It is not intended to be exhaustive or limiting to the precise form disclosed.

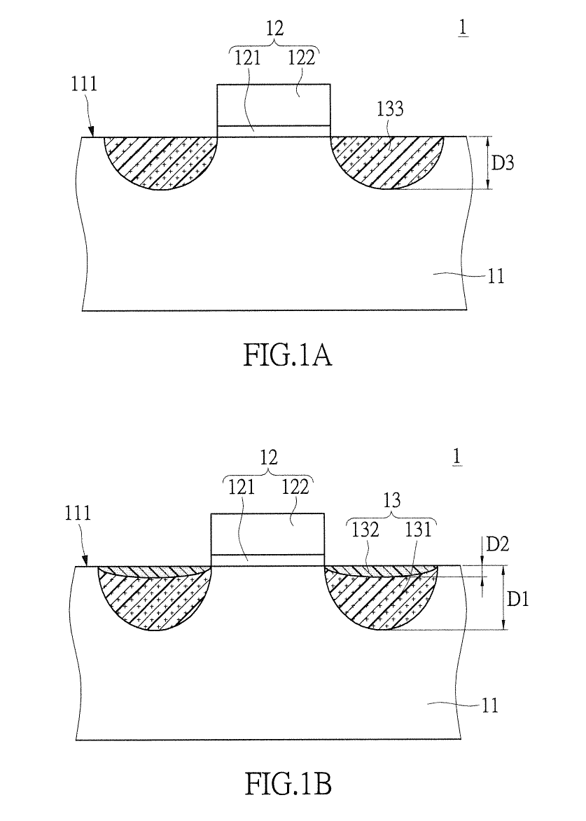

Please refer concurrently to FIGS. 1A and 1B. FIGS. 1A and 1B illustrate the steps showing a method of fabricating source/drain region of the present embodiment. According to the following embodiment of a method of fabricating source/drain region, for example, a source/drain region 13 is fabricated in a p-channel Metal Oxide Semiconductor Field Effect Transistor (hereinafter referred to as pMOS).

As shown in FIG. 1A, a substrate 11, such as an n-type silicon substrate formed by epitaxial growth, is first provided. Alternatively, the substrate 11 may be an SOI (Silicon On Insulator) substrate. A gate 12 is disposed on a surface 111 of the substrate 11. Specifically, the gate 12 may include a gate insulating layer 121 formed on the surface 111 of the substrate 11 and a gate electrode 122 stacked on the gate insulating layer 121. The gate insulating layer can be formed of a film having a high dielectric constant. The gate electrode can be made of polysilicon including impurities therein, or aluminum.

An ion beam-line of a first material, such as boron gas, is subsequently introduced to the surface 111 of the substrate 11 at a first energy and a first dosage to implant the substrate 11 with dopants of a first conductive type. Specifically, impurity dopants, such as boron, are introduced by the beam-line ion implantation, such that an initial ion-introduced region is formed in the substrate 11. The beam-line ion implantation is conducted at a first energy in a range of 0.9 to 3 KeV and a first dosage in a range of 1E14 to 1E16 dopant atoms/cm3.

The initial ion-introduced portion 133 extends from the surface 111 of the substrate 11 into the substrate 11 and has a depth D3 from the surface 111 towards the depth (thickness) direction of the substrate 11.

In a preferred embodiment, the beam-line ion implantation is conducted at the first energy of about 1 KeV with the first dosage of about 5×10¹⁴ dopant atoms/cm3.

Next, please refer to FIG. 1B. A plasma of a second material is introduced to the area of the surface 111, where the ion beam-line is introduced to implant the substrate 11 with dopants of the same first conductive type. For example, a reaction gas of the second material, such as B₂H₆, or BF₃, which contains impurity to be introduced, is excited in plasma, and the plasma is introduced to the surface 111 of the substrate 11 thus implanting the substrate 11 with boron dopants. It is worth noting that, the plasma implantation (hereinafter referred to as PLAD) is conducted at a second energy and with a second dosage, which is greater than the first dosage. In addition, the implant depth of the plasma is less than the implant depth of the ion beam-line.

Therefore, a second ion-introduced portion 132 is formed in the substrate 11 having a depth D2 from the surface 111 towards the depth (thickness) direction of the substrate 11. The second ion-introduced portion 132 extends from the surface 111 of the substrate 11 into the initial ion introduced portion 133. In addition, through the plasma implantation, the impurity dopants in the initial ion introduced portion 133 out diffuse into the substrate 11, thus, a first ion introduced portion 131 is formed that surrounds the second ion introduced portion 132 in the substrate 11. The dopant concentration of the second ion introduced portion 132 is greater than the dopant concentration of the first ion introduced portion 131. The dopant purity of the first ion introduced portion 131 is greater than the dopant purity of the first ion introduced portion 131.

It is considered that according to the present disclosure, with the energy of the impurity dopants introduced through the plasma impacting into the initial ion introduced portion 133, the impurity dopants in the initial ion introduced portion 133 is moved, thus diffusing out into and a deep region within the substrate 11, so as to form the first ion introduced portion 131 surrounding the second ion introduced portion 132 and having a depth D1, which is greater than the depth D3 and the depth D2. Hence, the source/drain region fabrication method of the present disclosure enables the formation of a source/drain region 13 that has the first ion introduced portion 131 of preferred dopant purity surrounding the second ion introduced portion 132, with high accuracy.

As a specific example, the second energy is in a range of 0.5 to 10 KeV, and the second dosage is in a range of 1E15 to 1E17 dopant atoms/cm3. Through PLAD, even when the impurity is boron, it is possible to form the shallow second ion introduced portion 132 in the substrate 11 having the depth D2 from the surface 111 towards the depth (thickness) direction of the substrate 11 in a range of 1 to 40 nanometers.

The first ion introduced portion 131 has the depth D1 from the surface 111 towards the depth (thickness) direction of the substrate 11 in a range of 1 to 40 nanometers. The depth D1 of the first ion introduced portion 131 is greater than the depth D3 of the initial ion-introduced portion 133.

In a preferred embodiment, the PLAD is conducted at the second energy of about 2.65 KeV with the second dosage of about 3.5×10¹⁶ dopant atoms/cm3.

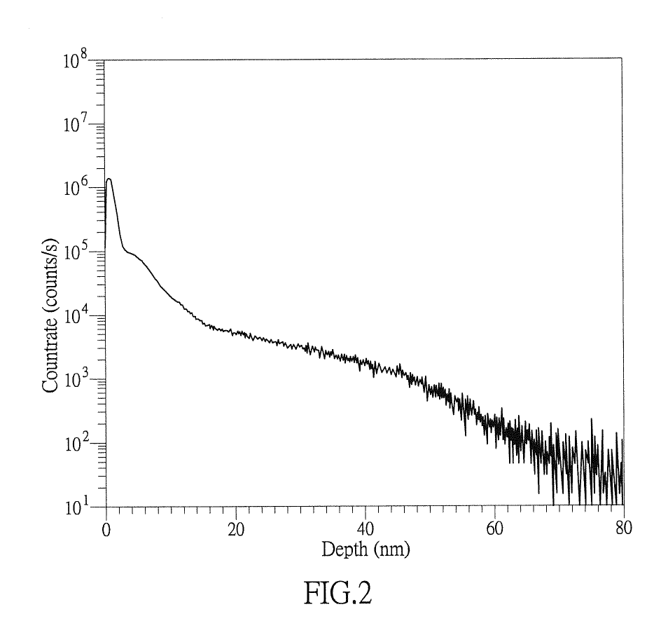

Thereafter, although not shown in FIG. 2C, a thermal treatment such as RTP (rapid thermal process) and/or annealing is applied to the substrate 11. An annealing treatment such as a flash lamp annealing (FLA), a laser annealing or the like can be adopted.

Here, at both sides of the gate 12, the impurity diffusion layers that serving as the source/ drain regions, are formed in the substrate 11 respectively.

In an alternative embodiment, a reaction gas of B₂H₆ which is mixed with He (helium) is supplied and excited in plasma. In another embodiment, the impurity dopants can be selected from a group consisting of B, As, P, Sb and In.

In accordance with the instant embodiment, the present disclosure also provides a semiconductor structure 1. As shown in FIG. 1B, the semiconductor structure 1 includes an n-type semiconductor substrate 11, a gate 12 disposed on a surface 111 of the substrate 11, and a source/drain region 13 for the gate 12 disposed within the substrate 11. The gate 12 may include a gate insulating layer 121 formed on the surface 111 of the substrate 11 and a gate electrode 122 stacked on the gate insulating layer 121. At both sides of the gate 12 insulating film, in the semiconductor substrate 11, two of the source/drain regions 13 are formed, respectively.

The source/drain regions 13 each have a first ion introduced portion 131 and a second ion introduced portion 132 extending from the surface 111 of the substrate 11 into the substrate 11. The first ion introduced portion 131 surrounds the second ion introduced portion 132 and does not underlap the gate 12. The second ion introduced portion 132 has a dopant concentration greater than that of the first ion introduced portion 131. The first ion introduced portion 131 has a dopant purity greater than that of the second ion introduced portion 132.

The source/drain regions 13 are electrically connected to a source electrode and a drain electrode (not shown in the Figures), respectively. In a case where a predetermined voltage (gate voltage) is applied to the gate electrode 122, an inversion layer, i.e., a channel is formed in the substrate 11. In a case where a predetermined voltage is applied to the source electrode and drain electrode, a current flows between the source/drain regions 13 via the channel.

Please refer to FIG. 2, which is a view showing SIMS data showing impurity profiles of a source/drain region of the semiconductor structure which is obtained by an embodiment of the instant disclosure. The impurity profile is measured using an SIMS in the instant disclosure. From FIG. 2, it can be understood that the source/drain region 13, which is formed by the method of the present disclosure, exhibits the impurity concentration at a depth position of about 2 nm which is 1/10 of the impurity concentration near the vicinity of the surface 111 of the substrate 11 and exhibits the impurity concentration at a depth position of about 12 nm which is 1/100 of the impurity concentration near the vicinity of the surface 111 of the substrate 11.

To sum up, the source/drain region 13 is formed by performing ion beam-line implantation of p-type impurities (for example boron) and, then by performing PLAD implantation of p-type impurities (for example boron).

In the step of ion beam-line implantation, the ion beam-line of the material which contains the impurity to be introduced is introduced onto the surface 111 of the substrate 11 merely at a relatively low energy compared with the conventional process that adapts the ion beam-line implantation.

Through such arrangement, the source/drain region 13 of high dopant concentration with low resistance at the relative shallow region near the vicinity of the surface 111 of the substrate 11 and high dopant purity at the relative deep region at the interface between two types of semiconductor material is formed for the miniaturization of a semiconductor device in the instant disclosure.

The higher concentration of dopants near the vicinity of the surface 111 of the source/drain region 13 has an advantage in resistivity where the source/drain region 13 is connected to other structures through a contact or an interconnecting layer. The first ion introduced portion 131 surrounding the second ion introduced portion 132 enables the source/drain region 13 to resume the higher purity of dopants at the interface between the source/drain region 13 and the well region, where current leakage can be prevented.

Various devices can be formed using such source/drain region. The present invention is applicable to the formation of the source/drain region which may enable the semiconductor structure to resume a smaller physical dimension and facilitate the miniaturization, the high integration such as the formation of a DRAM, or the formation of a liquid crystal panel where thin film transistors (TFT) or the like are integrated.

In the above-mentioned embodiment, the substrate to be treated is a substrate which forms a semiconductor device. In an alternative embodiment, the present disclosure of a method of fabricating source/drain region is applicable to a case when the substrate to be treated is a glass substrate that forms a liquid crystal display device and constitutes a matrix substrate.

While the invention has been disclosed with respect to a limited number of embodiments, numerous modifications and variations will be appreciated by those skilled in the art. It is intended, therefore, that the following claims cover all such modifications and variations that may fall within the true spirit and scope of the invention.

What is claimed is:

1. A method of fabricating source/drain region in a substrate, comprising:
introducing an ion beam-line of a first material to a surface of the substrate at a first energy and a first dosage to implant the substrate with dopants of a first conductive type; and
introducing a plasma of a second material to the surface, where the ion beam-line is introduced, at a second energy and a second dosage to implant the substrate with dopants of the first conductive type;
wherein the second dosage is greater than the first dosage and the implant depth of the plasma is less than the implant depth of the ion beam-line.

2. The method of fabricating source/drain region of claim 1, wherein the substrate is an n-type semiconductor substrate, the first material is boron gas, and the second material is B₂H₆ gas.

3. The method of fabricating source/drain region of claim 1, wherein the substrate is an n-type semiconductor substrate, the first material is boron gas, and the second material is BF₃ gas.

4. The method of fabricating source/drain region of claim 1, wherein the first energy is in a range of 0.9 to 3 KeV, the first dosage is in a range of 1E14 to 1E16 dopant atoms/cm3, the second energy is in a range of 0.5 to 10 KeV, and the second dosage is in a range of 1E15 to 1E17 dopant atoms/cm3.

5. The method of fabricating source/drain region of claim 1, wherein the first energy is about 1 KeV, the first dosage is about 5×10¹⁴ dopant atoms/cm3, the second energy is about 2.65 KeV, and the second dosage is about 3.5×10¹⁶ dopant atoms/cm3.

6. The method of fabricating source/drain region of claim 1, further comprising a step of: performing a thermal treatment on the substrate.

7. The method of fabricating source/drain region of claim 1, wherein in the step of introducing the ion beam-line comprises a step of:
introducing the ion beam-line to form an initial ion introduced portion extending from the surface of the substrate into the substrate; and
wherein the step of introducing the plasma comprises a step of:
introducing the plasma to form a second ion introduced portion extending from the surface of the substrate into the initial ion introduced portion,
wherein the dopants in the initial ion introduced portion diffuse into the substrate to form a first ion introduced portion surrounding the second ion introduced portion, the second ion introduced portion has a dopant concentration greater than a dopant concentration of the first ion introduced portion, and the first ion introduced portion has a dopant purity greater than dopant purity of the second ion introduced portion.

8. A semiconductor structure, comprising:
a substrate;
a gate disposed on a surface of the substrate; and
a source/drain region for the gate disposed in the substrate,
wherein the source/drain region has a first ion introduced portion and a second ion introduced portion extending from the surface of the substrate into the substrate;
wherein the first ion introduced portion surrounds the second ion introduced portion, the second ion introduced portion has a dopant concentration greater than a dopant concentration of the first ion introduced portion, and the first ion introduced portion has a dopant purity greater than a dopant purity of the second ion introduced portion.

9. The semiconductor structure of claim 8, wherein the first ion introduced portion does not underlap the gate.

10. The semiconductor structure of claim 8, wherein the substrate is an n-type semiconductor substrate and the source/drain region has dopants selected from a group consisting of B, As, P, Sb and In.

11. The semiconductor structure of claim 8, wherein the first ion introduced portion has a depth in a range of 1 to 40 nanometers, and the second ion introduced portion has a depth in a range of 1 to 40 nanometers.
